(19) United States
(12) Patent Application Publication
(10) Pub. No.: US 2025/0052524 A1
(43) Pub. Date: Feb. 13, 2025

(54) LIQUID-COOLING RADIATOR AND HEAT PIPE THEREOF

(71) Applicant: ACCTON TECHNOLOGY CORPORATION, Hsinchu (TW)

(72) Inventor: TING-JUI CHANG, New Taipei City (TW)

(73) Assignee: ACCTON TECHNOLOGY CORPORATION, Hsinchu (TW)

(21) Appl. No.: 18/409,787

(22) Filed: Jan. 10, 2024

(30) Foreign Application Priority Data
Aug. 8, 2023 (CN) 202322117923.2

(51) Int. Cl. F28F 9/26; F28D 15/02

(52) U.S. Cl. CPC F28F 9/266; F28D 15/0275; F28F 2275/143; F28F 2275/20

(57) ABSTRACT

A liquid-cooling radiator includes a heat sink. The heat sink has a heat pipe opening on a surface of the heat sink and a heat pipe chamber inside the heat sink which communicates with the heat pipe opening. A pressure device is disposed in the heat pipe chamber. A heat pipe is disposed between the heat pipe opening and the pressure device. The heat pipe has a flexible pipe body. The pipe body has a flow channel therein. A part of the pipe body protrudes from the heat pipe opening and is exposed from the surface of the heat sink.

### BACKGROUND OF THE INVENTION

### Technical Field

The present disclosure relates generally to a radiator, and more particularly to a liquid-cooling radiator and a heat pipe thereof.

### Description of Related Art

A conventional water-cooling radiator typically has a heat sink having cooling fins and arranged around a heat pipe. A cooling fluid in the heat pipe can take heat away from the heat sink and an object to be cooled which the heat sink contacts, thereby cooling the object to be cooled.

In the above-mentioned conventional water-cooling radiator, as heat is transferred between the heat pipe and the heat sink through heat conduction, the larger the contact area between the heat pipe and the heat sink, the better the heat dissipation efficiency. An existing method is to weld the cooling fins around the heat pipe or add a thermoconductive material between the heat pipe and the heat sink, thereby improving the heat dissipation efficiency of the water-cooling radiator.

### BRIEF SUMMARY OF THE INVENTION

In view of the above, the primary objective of the present disclosure is to provide a liquid-cooling radiator, wherein a flexible heat pipe and a pressure device capable of pressing the heat pipe are disposed inside the liquid-cooling radiator and a part of the heat pipe protrudes from a heat sink to be in contact with an object to be cooled, thereby achieving a better heat dissipation efficiency.

The present disclosure provides a liquid-cooling radiator, including a heat sink, a pressure device, and a heat pipe. The heat sink has a heat pipe chamber. The heat pipe chamber has an inlet/outlet port. A surface of the heat sink has a contact portion. The contact portion has at least one heat pipe opening. The at least one heat pipe opening communicates with the heat pipe chamber. The pressure device is disposed in the heat pipe chamber. The heat pipe is disposed in the heat pipe chamber and has a pipe body that is flexible. A flow channel is formed in the pipe body. Two ends of the flow channel respectively have a flow channel inlet and a flow channel outlet matching with the inlet/outlet port. Two opposite sides of the pipe body respectively have a cooling surface and an abutting surface. The cooling surface faces the contact portion. The abutting surface faces the pressure device. At least part of the cooling surface is exposed to the contact portion from the at least one heat pipe opening.

The present disclosure has the following beneficial effects: When the cooling fluid is introduced to the heat pipe to be circulated in the heat pipe and the contact portion of the heat sink tightly abuts against the surface of the object to be cooled, the surface of the object to be cooled presses the part of the pipe body protruding from the contact portion back into the heat pipe chamber, so that the part of the cooling surface on the inner side of the heat pipe openings and the surface of the contact portion could be tightly attached to the surface of the object to be cooled together. In this way, the present disclosure has a better heat conduction effect since the part of the pipe body is directly in contact with the surface of the object to be cooled.

In addition, when the part of the pipe body protruding from the contact portion is pressed back into the heat pipe chamber by the object to be cooled, the pressure device inside the heat pipe chamber could function as a buffer, so that the protruding part of the pipe body could be smoothly pressed into the heat pipe chamber without being damaged due to excessive pressure. At the same time, other parts of the pipe body could also be tightly attached to the wall surface of the heat pipe chamber under the pressure of the pressure device, thereby achieving a better heat conduction effect between the heat pipe and the heat sink.

### BRIEF DESCRIPTION OF THE SEVERAL VIEWS OF THE DRAWINGS

The present disclosure will be best understood by referring to the following detailed description of some illustrative embodiments in conjunction with the accompanying drawings, in which

FIG. 1 is a perspective view of the liquid-cooling radiator according to an embodiment of the present disclosure;

FIG. 2 is an exploded view of the liquid-cooling radiator according to the embodiment of the present disclosure;

FIG. 3 is an exploded view of the liquid-cooling radiator according to the embodiment of the present disclosure seen from another perspective;

FIG. 4 is an exploded view of the liquid-cooling radiator according to the embodiment of the present disclosure, showing the pressure device is not separated from the heat sink body;

FIG. 5 is a schematic perspective view, showing a section of a part of the heat pipe according to the embodiment of the present disclosure;

FIG. 6 is a front view of the heat pipe according to the embodiment of the present disclosure;

FIG. 7A is a sectional view along the line A1-A1 in FIG. 6;

FIG. 7B is a schematic sectional view of the pipe body according to another embodiment of the present disclosure;

FIG. 7C is a schematic sectional view of the pipe body according to still another embodiment of the present disclosure;

FIG. 8 is a top view of the liquid-cooling radiator according to the embodiment of the present disclosure;

FIG. 9 is a sectional view along the line A2-A2 in FIG. 8;

FIG. 10 is a sectional view along the line A3-A3 in FIG. 8;

FIG. 11 is a schematic perspective view, showing the liquid-cooling radiator according to the embodiment of the present disclosure mounted to the object to be cooled; and

FIG. 12 is a schematic sectional view, showing the liquid-cooling radiator according to the embodiment of the present disclosure mounted to the object to be cooled.

### DETAILED DESCRIPTION OF THE INVENTION

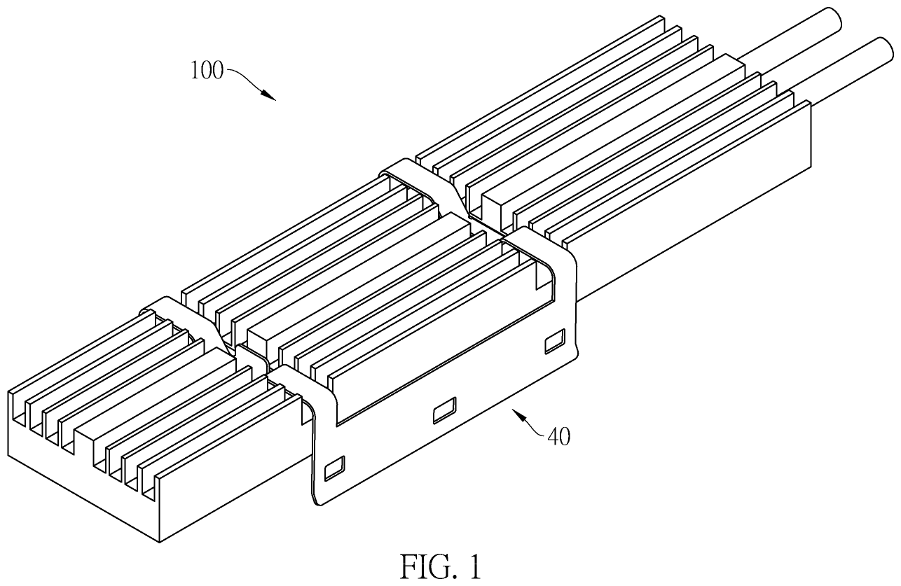

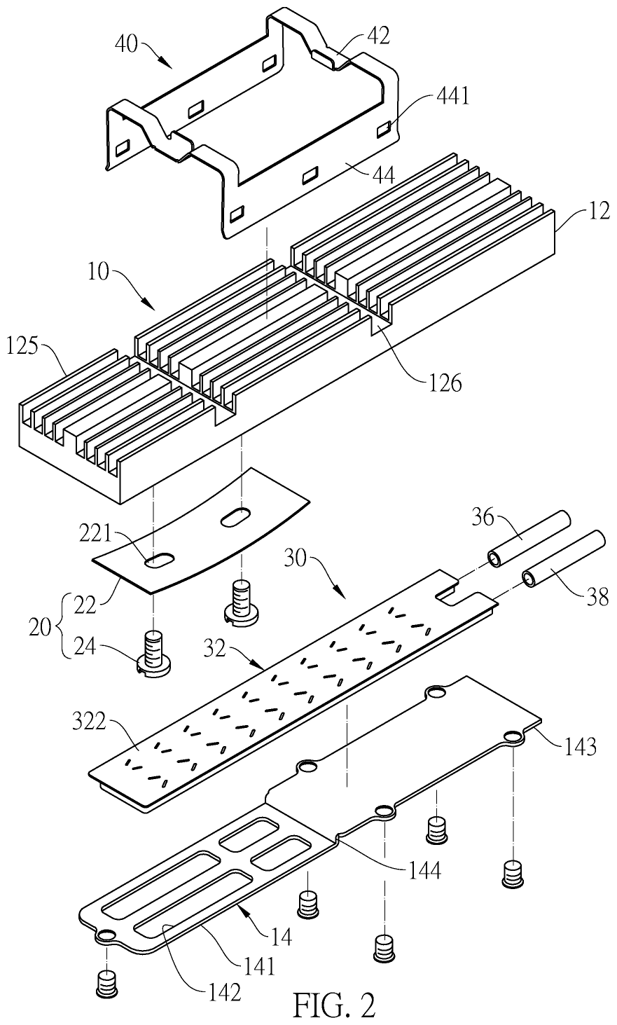

A liquid-cooling radiator 100 according to an embodiment of the present disclosure is illustrated in FIG. 1 to FIG. 5 and includes a heat sink 10, and a pressure device 20 and a heat pipe 30 respectively disposed in the heat sink 10. The liquid-cooling radiator 100 is used in cooperation with a fastener 40 adapted to fix the heat sink 10.

The heat sink 10 includes a heat sink body 12 and a bottom plate 14. The heat sink body 12 is a metal block with good thermal conductivity. A heat pipe chamber 121 is provided in the heat sink body 12. An end of the heat sink body 12 has an inlet/outlet port 122 communicating with the heat pipe chamber 121. The heat pipe chamber 121 forms a bottom plate opening 123 on a bottom side of the heat sink body 12. A periphery of the bottom plate opening 123 has a stepped portion 124. The bottom plate opening 123 communicates with the inlet/outlet port 122. A surface of a top side of the heat sink body 12 has a plurality of cooling fins 125. Two fastening grooves 126 are arranged at an interval between the plurality of cooling fins 125.

The bottom plate 14 is engaged with the bottom plate opening 123 in a detachable manner relative to the heat pipe chamber 121. The bottom plate 14 is a metal plate body with good thermal conductivity. A periphery of the bottom plate 14 is embedded in the stepped portion 124 and is engaged with the heat sink body 12 through screwing. A side of the bottom plate 14 close to the inlet/outlet port 122 is provided with a separation portion 143, and another side of the bottom plate 14 away from the inlet/outlet port 122 has a contact portion 141. A connecting section 144 is connected between the separation portion 143 and the contact portion 141. A position of the separation portion 143 is recessed toward the heat sink body 12 to be closer to the heat sink body 12 than a position of the contact portion 141. A surface of the contact portion 141 is a flat surface adapted to be in contact with a surface of an object to be cooled and is located on a bottom side of the heat sink 10. The contact portion 141 has at least one heat pipe opening 142. The at least one heat pipe opening 142 communicates with the heat pipe chamber 121. In the current embodiment, the contact portion 141 has four heat pipe openings 142 arranged in a matrix arrangement, and a contour of each of the heat pipe openings 142 is substantially rectangular. In other embodiments, the contact portion 141 could be provided with only one heat pipe opening 142, and the contour of the heat pipe opening 142 is not limited to a rectangle, but could be a circle, a polygon, or other shapes.

Apart from the embodiment of the present disclosure, in which the heat sink 10 is designed to include at least two separate components such as the heat sink body 12 and the bottom plate 14, the heat sink 10 could be designed as an integrated metal structure that combines the aforementioned components and has good thermal conductivity. In this case, the heat sink 10 has the heat pipe chamber 121 therein. The inlet/outlet port 122 communicating with the heat pipe chamber 121 is disposed on a side of the heat pipe chamber 121. Moreover, such integrated heat sink 10 also has a contact portion 141, wherein the contact portion 141 is provided with at least one heat pipe opening 142 communicating with the heat pipe chamber 121.

The pressure device 20 is disposed in the heat pipe chamber 121. In the current embodiment, the pressure device 20 is coupled to a top wall of the heat pipe chamber 121 and faces the contact portion 141 at an interval. The pressure device 20 is flexible, so that the pressure device 20 could be released to restore to an original position or an original shape after being compressed. The pressure device 20 could be various types of elastic pieces, spring assemblies or polymer (e.g., rubber) elastic blocks. In other embodiments, the pressure device 20 could also be disposed at other positions in the heat pipe chamber 121 that could be pressed by the heat pipe 30.

The heat pipe 30 is disposed in the heat pipe chamber 121 and has a pipe body 32 that is flexible. The pipe body 32 could be integrally formed or be formed by connecting multiple different components. In the current embodiment, the pipe body 32 is integrally formed as a monolithic unit and has a TPU (thermoplastic polyurethane) thin wall. A flow channel 34 is formed in the pipe body 32. Two ends of the flow channel 34 respectively have a flow channel inlet 341 and a flow channel outlet 342 that are adapted to match with the inlet/outlet port 122. In other embodiments, the pipe body 32 could also be made of other thermoplastic or rubber materials.

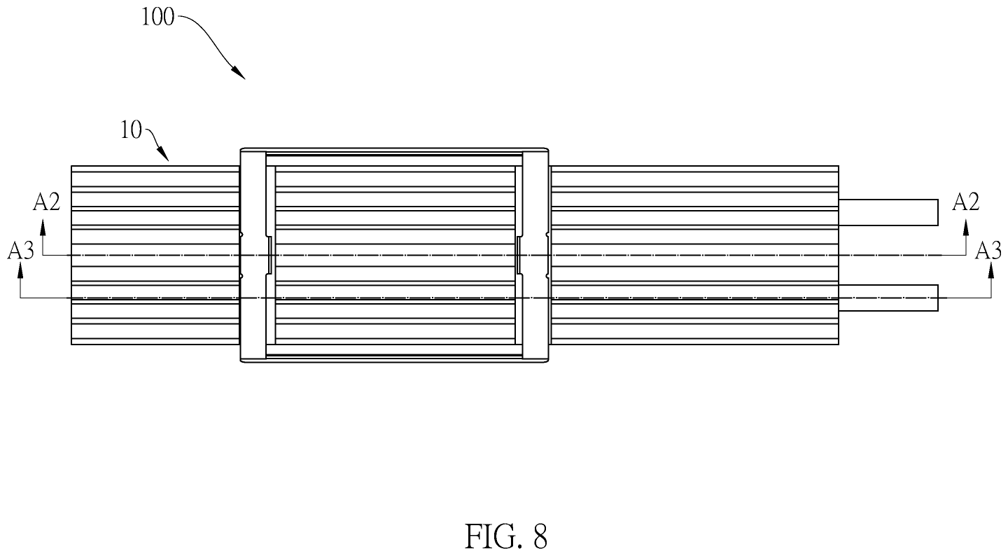

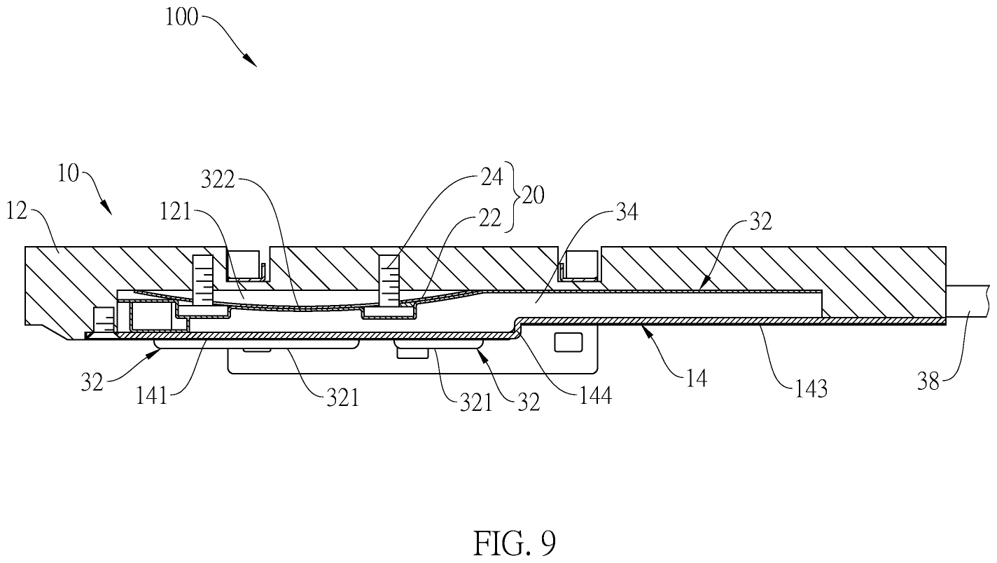

Two opposite sides of the pipe body 32 respectively have a cooling surface 321 and an abutting surface 322. The cooling surface 321 faces the contact portion 141, and the abutting surface 322 faces the pressure device 20. Referring to FIG. 8 to FIG. 10, a part of the pipe body 32 is subjected to the pressure of the pressure device 20 to protrude from each of the heat pipe openings 142 due to the flexibility of the pipe body 32, so that at least part of the cooling surface 321 is exposed to the contact portion 141. Specifically, the at least part of the pipe body 32 is located between the contact portion 141 and the pressure device 20. When the pipe body 32 is placed in the heat pipe chamber 121 and the abutting surface 322 abuts against the pressure device 20, the pipe body 32 is pressed by the pressure device 20 such that the part of the pipe body 32 protrudes from each of the heat pipe openings 142, and thus, the at least part of the cooling surface 321 is exposed to the contact portion 141.

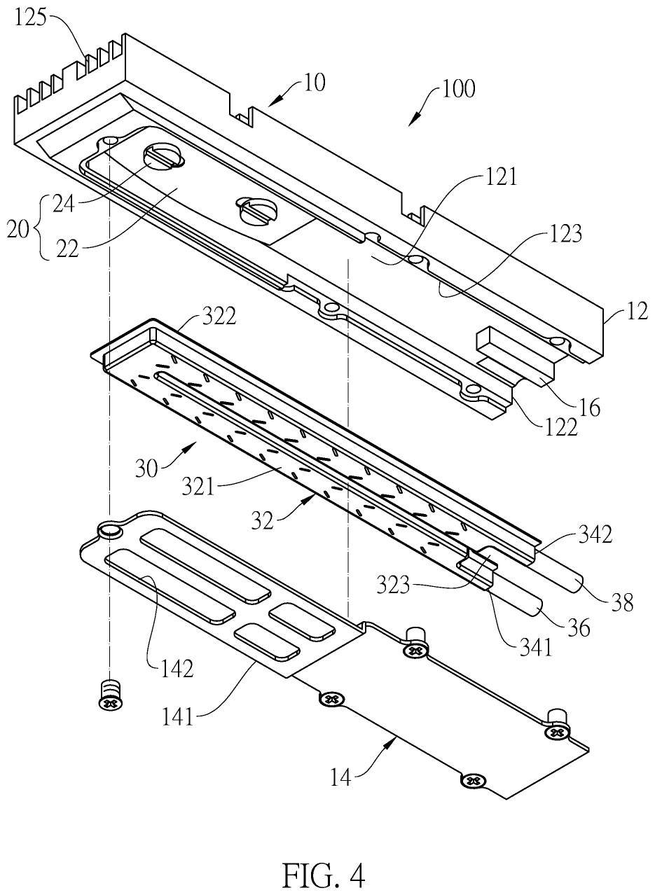

Referring to FIG. 4 and FIG. 9 to FIG. 10, when the present disclosure is in use, an inlet pipe 36 and an outlet pipe 38 are respectively connected to the flow channel inlet 341 and the flow channel outlet 342 of the heat pipe 30. A cooling fluid is injected from the inlet pipe 36 into the flow channel 34 of the heat pipe 30 through the flow channel inlet 341. After flowing into the flow channel 34, the cooling fluid flows out of the flow channel outlet 342 to the outlet pipe 38.

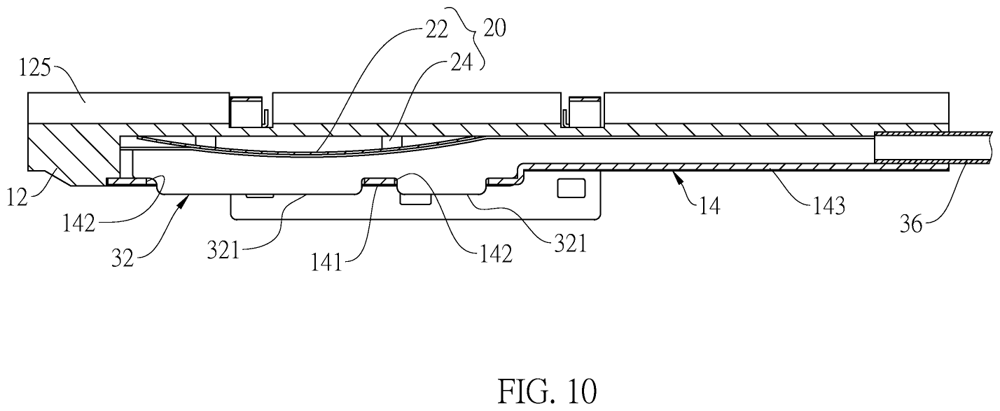

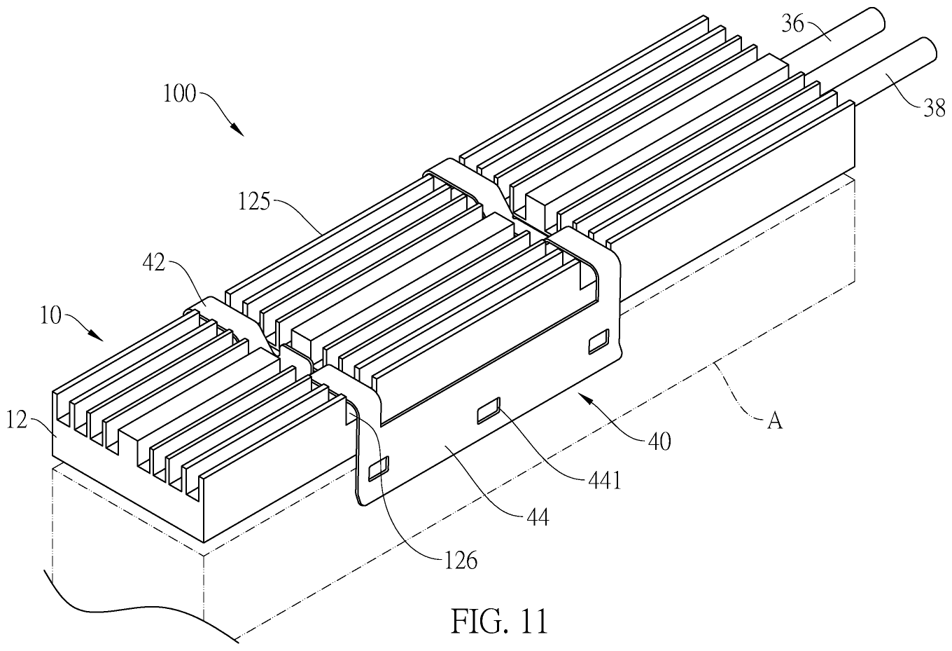

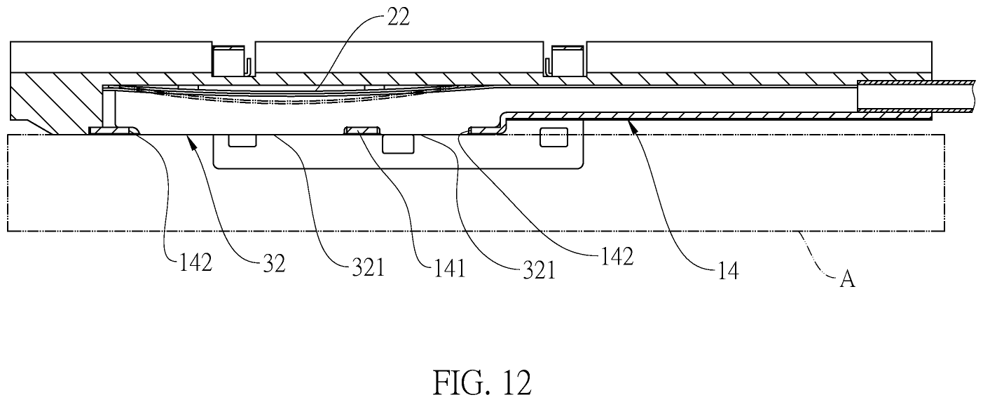

Referring to FIG. 10 to FIG. 12, when the liquid-cooling radiator 100 is to be mounted to an object to be cooled A, the fastener 40 is used to fasten the heat sink 10 to the object to be cooled A, so that the contact portion 141 of the heat sink 10 tightly abuts against a surface of the object to be cooled A. Specifically, in order to cooperate with the fastening grooves 126 of the heat sink body 12, the fastener 40 is provided with two elastic fastening pieces 42 arranged at an interval. The two elastic fastening pieces 42 respectively pass through the fastening grooves 126. Two fastening plate 44 are respectively engaged between two opposite sides of the two elastic fastening pieces 42 that are on the same side. A bottom side of each of the fastening plates 44 has a plurality of fastening holes 441 arranged at intervals. The two fastening plates 44 are fastened to two opposite sides of the object to be cooled A by the plurality of fastening holes 441, and the two elastic fastening pieces 42 elastically press the heat sink body 12, so that the heat sink body 12 tightly abuts against the surface of the object to be cooled A. In other embodiments, only one fastening groove 126 could be provided between the plurality of cooling fins 125; in this case, the fastener 40 is provided with only one elastic fastening piece 42; the elastic fastening piece 42 passes through the fastening groove 126; two sides of the elastic fastening piece 42 are respectively engaged with a fastening plate 44; a bottom side of each of the fastening plates 44 has a fastening hole 441; the two fastening plates 44 are fastened to the two opposite sides of the object to be cooled A by the fastening holes 441.

In the process of mounting the heat sink 10 on the object to be cooled A, the surface of the object to be cooled A presses the part of the flexible pipe body 32 protruding from the contact portion 141 back into the heat pipe chamber 121. The pressure device 20 that is compressible is disposed at a position in the heat pipe chamber 121 corresponding to the heat pipe openings 142, so that when the part of the pipe body 32 protruding from the heat pipe openings 142 is pressed, the pressure device 20 could bear the pressure and become deformed so as to function as a buffer. In this way, the protruding part of the pipe body 32 could be smoothly pressed back into the heat pipe chamber 121 when pressed, so that the pipe body 32 and the heat sink body 12 would not be damaged due to excessive pressure.

At the same time, the pressure device 20 could also press the pipe body 32 such that the surface of the pipe body 32 is tightly attached to a peripheral wall surface of the heat pipe chamber 121, thereby realizing good heat conduction between the heat pipe 30 and the heat sink 10. After the heat sink 10 is mounted, a part of the cooling surface 321 located on an inner side of the heat pipe openings 142 and a surface of the contact portion 141 could be tightly attached to the surface of the object to be cooled A together, so that the present disclosure has a better heat conduction effect since the part of the pipe body 32 could be directly in contact with the surface of the object to be cooled A.

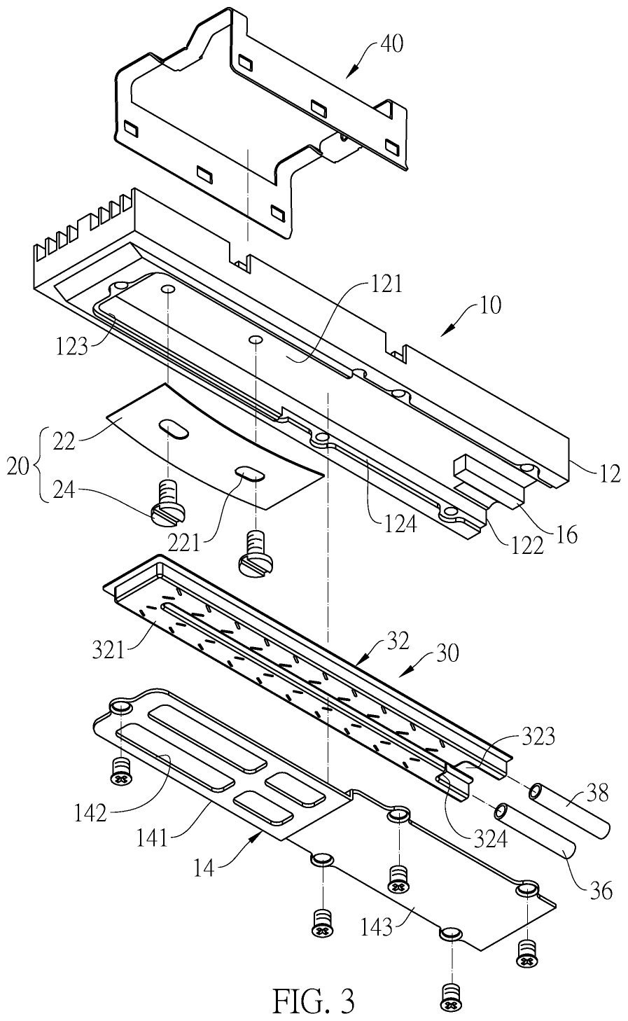

Referring to FIG. 3, in order to position the heat pipe 30 in the heat pipe chamber 121, the heat sink body 12 in the current embodiment has a stopper 16. The stopper 16 is located at a middle of the inlet/outlet port 122. In the current embodiment, the flow channel 34 is U-shaped, and the flow channel inlet 341 and the flow channel outlet 342 face a same direction, i.e., face the inlet/outlet port 122. A notch 323 is formed at a part of the pipe body 32 located between the flow channel inlet 341 and the flow channel outlet 342. A part of the pipe body 32 adjacent to an inner side of the notch 323 has a stopping surface 324. The stopper 16 extends into the notch 323, and the stopping surface 324 and the stopper 16 are opposed to each other, so that the stopping surface 324 could position the pipe body 32 in the heat pipe chamber 121 by being restricted by the stopper 16, thereby preventing the pipe body 32 from being removed through the inlet/outlet port 122.

Referring to FIG. 3 to FIG. 4, the pressure device 20 of the current embodiment of the present disclosure includes a flat spring 22 and at least one fixing member 24. The flat spring 22 is an arc-shaped elastic sheet. The flat spring 22 has at least one fixing hole 221. In the current embodiment, the number of the fixing member 24 and the number of the fixing hole 221 are plural, wherein each of the fixing members 24 passes through one of the fixing holes 221 to be engaged with the top wall of the heat pipe chamber 121 for fixing. In this way, in the process of assembling the liquid-cooling radiator 100, when the pipe body 32 is placed in the heat pipe chamber 121 and the bottom plate 14 is engaged with the bottom plate opening 123, the abutting surface 322 of the pipe body 32 abuts against the flat spring 22 to be pressed by the flat spring 22, so that the part of the pipe body 32 protrudes out of the contact portion 141 from the heat pipe openings 142. Moreover, when the part of the pipe body 32 protruding from the contact portion 141 is pressed by the object to be cooled A, buffer could be obtained by compressing the flat spring 22. In other embodiments, the flat spring 22 could also be provided with only one fixing hole 221, and one fixing member 24 passes through the fixing hole 221 to engage the flat spring 22 with the heat pipe chamber 121.

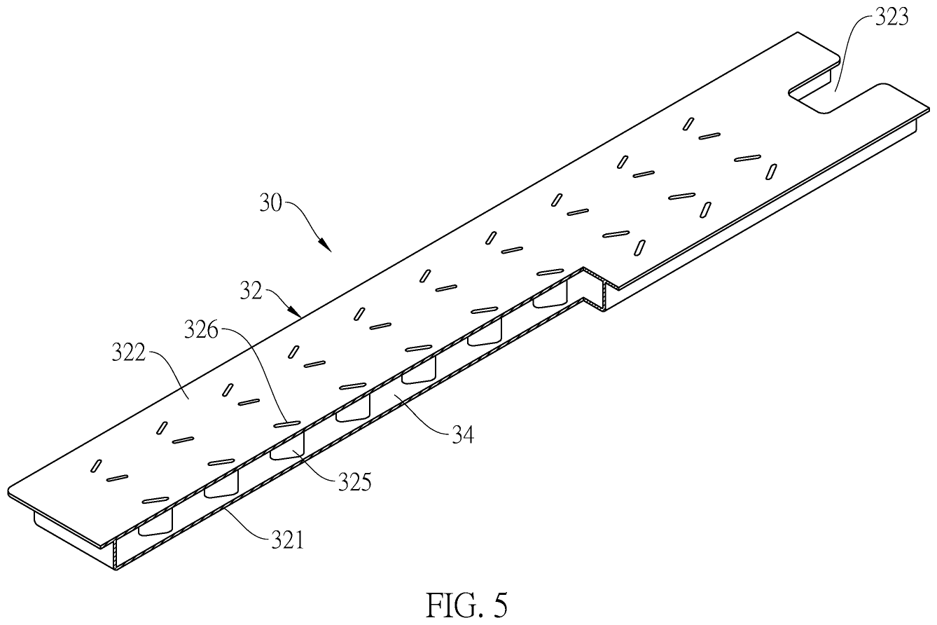

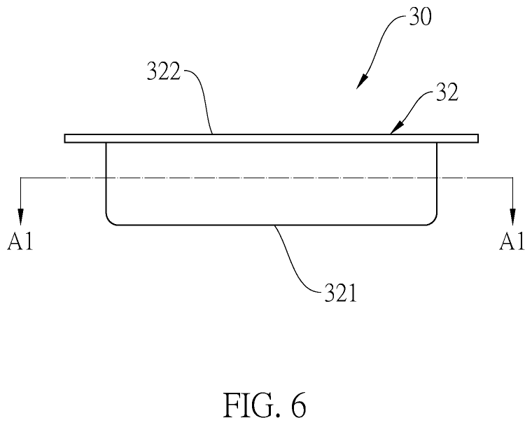

Referring to FIG. 5 to FIG. 7A, the heat pipe 30 in the current embodiment has at least one fin 325 that is flexible and is disposed between a top wall and a bottom wall of the flow channel 34. In the current embodiment, a number of the fin 325 is plural, and the fins 325 are arranged at intervals along an extending direction of the flow channel 34. The plurality of fins 325 in the flow channel 34 have the following functions: Based on the formula that the flow rate divided by the sectional area is equal to the flow velocity, when the flow rate of the fluid inputted into the flow channel 34 changes, the change in the flow channel 34 makes the flexible fins 325 deformed or displaced correspondingly, so that the effective sectional area of the flow channel 34 could be adjusted with the change of the flow rate. Thus, the flow rate of the fluid passing through the flow channel 34 is approximately in direct proportion to the sectional area, so that the heat dissipation efficiency of the heat pipe 30 could be improved by adjusting the flow velocity of the fluid passing through the flow channel 34. It is worth mentioning that in the current embodiment, the number of fin 325 is plural as an example; however, in other embodiments, the number of fin 325 could be only one.

In the current embodiment, each of the fins 325 has a through hole 326, wherein each of the through holes 326 penetrates through the cooling surface 321 and the abutting surface 322. Specifically, the plurality of fins 325 are sheet-like, and the fins 325 are grouped in pairs. The pairs of fins 325 are arranged at intervals along the extending direction of the flow channel 34. A flow direction of the fluid in the flow channel 34 toward the flow channel outlet 342 is defined as a downstream direction L1 and a flow direction of the fluid in the flow channel 34 toward the flow channel inlet 341 is defined as an upstream direction L2. A distance between two ends of each of the pairs of fins 325 facing the upstream direction L2 is larger, and a distance between two another ends of each of the pairs of fins 325 facing the downstream direction L1 is smaller. With the plurality of fins 325 disposed inside the heat pipe 30, the heat pipe 30 of the present disclosure could increase the contact area between the cooling fluid in the flow channel 34 and an inner wall of the pipe body 32, thereby improving the efficiency of heat exchange between the cooling fluid flowing in the flow channel 34 and the heat pipe 30 by heat conduction. In other embodiments, the fins 325 could also be disposed in the flow channel 34 without the through hole 326.

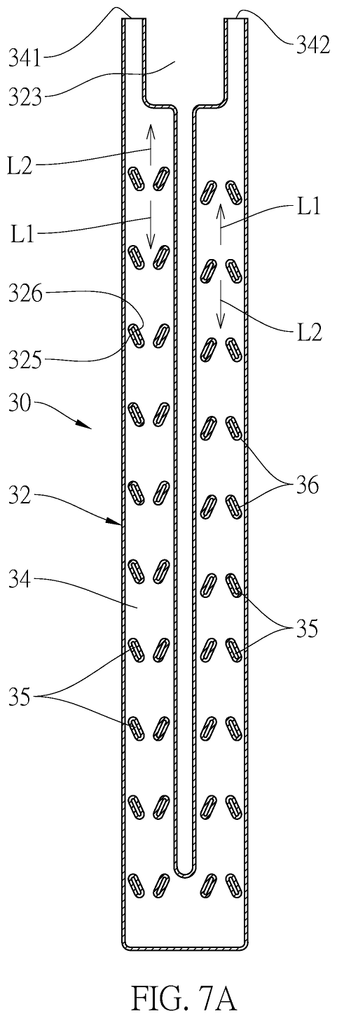

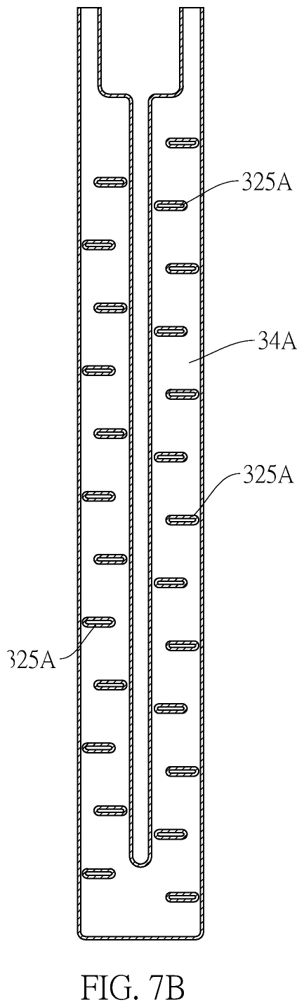

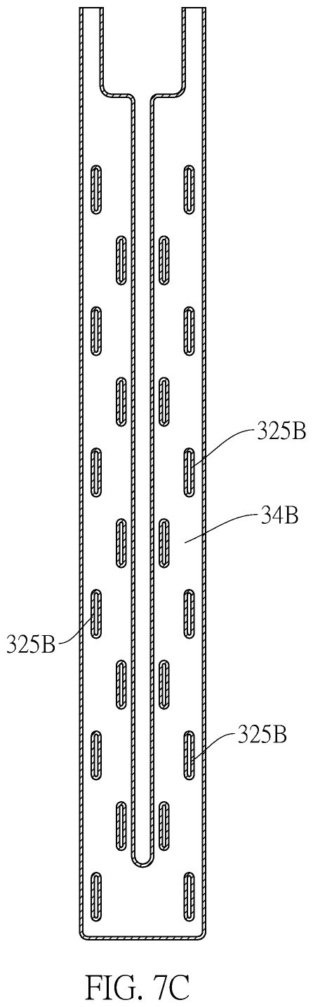

In the aforementioned embodiment of the present disclosure, the plurality of fins 325 are arranged in pairs in the heat pipe 30 and at intervals along the extending direction of the flow channel 34. However, referring to FIG. 7B, in another embodiment of the present disclosure, a plurality of fins 325A is sheet-like and is configured in a direction perpendicular to an extending direction of a flow channel 34A, and the fins 325A are disposed along the extending direction of the flow channel 34A and are arranged in a staggered arrangement along a direction (i.e., a left-right direction) perpendicular to the extending direction of the flow channel 34A. Alternatively, referring to FIG. 7C, in still another embodiment of the present disclosure, a plurality of fins 325B is sheet-like and is configured in a direction the same as an extending direction of a flow channel 34B, and the fins 325B are disposed along the extending direction of the flow channel 34B and are arranged in a staggered arrangement along the left-right direction.

It must be pointed out that the embodiments described above are only some preferred embodiments of the present disclosure. All equivalent structures which employ the concepts disclosed in this specification and the appended claims should fall within the scope of the present disclosure.

What is claimed is:

1. A liquid-cooling radiator, comprising:
a heat sink, having a heat pipe chamber and a contact portion, wherein the heat pipe chamber has an inlet/outlet port; the contact portion has at least one heat pipe opening; the at least one heat pipe opening communicates with the heat pipe chamber;
a pressure device, disposed in the heat pipe chamber; and
a heat pipe, disposed in the heat pipe chamber and having a pipe body that is flexible; the pipe body has a flow channel, wherein the flow channel has a flow channel inlet and a flow channel outlet matching with the inlet/outlet port; two opposite sides of the pipe body respectively have a cooling surface and an abutting surface, wherein the cooling surface faces the contact portion and the abutting surface faces the pressure device; at least part of the cooling surface is exposed to the contact portion from the at least one heat pipe opening.

2. The liquid-cooling radiator as claimed in claim 1, wherein the heat sink has a heat sink body and a bottom plate; the heat pipe chamber is provided in the heat sink body; the inlet/outlet port is disposed on an end of the heat sink body; the heat pipe chamber forms a bottom plate opening at the heat sink body, the bottom plate is engaged with the bottom plate opening; the contact portion and the at least one heat pipe opening are provided on the bottom plate.

3. The liquid-cooling radiator as claimed in claim 2, wherein the heat sink body has a stopper; the stopper is located at a middle of the inlet/outlet port; the flow channel inlet and the flow channel outlet of the flow channel face a same direction; a notch is formed at a part of the pipe body located between the flow channel inlet and the flow channel outlet; a part of the pipe body adjacent to an inner side of the notch has a stopping surface; the stopper is located in the notch and opposed to the stopping surface.

4. The liquid-cooling radiator as claimed in claim 3, wherein a side of the bottom plate close to the inlet/outlet port is provided with a separation portion; the contact portion is disposed on another side of the bottom plate away from the inlet/outlet port; a connecting section is connected between the separation portion and the contact portion; a position of the separation portion is recessed to be closer to the heat sink body than a position of the contact portion.

5. The liquid-cooling radiator as claimed in claim 1, wherein the pressure device comprises a flat spring and at least one fixing member; the flat spring is an arc-shaped elastic sheet; the flat spring has at least one fixing hole; the at least one fixing member passes through the at least one fixing hole to engage the flat spring with the heat pipe chamber; the abutting surface of the pipe body abuts against the flat spring.

6. The liquid-cooling radiator as claimed in claim 2, wherein a surface of the heat sink body has a plurality of cooling fins; a fastening groove is disposed between the plurality of cooling fins; a fastener is provided in cooperation with the heat sink; the fastener is provided with an elastic fastening piece; the elastic fastening piece passes through the fastening groove, wherein two sides of the elastic fastening piece are respectively engaged with a fastening plate; a bottom side of the fastening plate has a fastening hole.

7. The liquid-cooling radiator as claimed in claim 1, wherein at least one fin that is flexible is disposed in the flow channel.

8. The liquid-cooling radiator as claimed in claim 2, wherein at least one fin that is flexible is disposed in the flow channel.

9. The liquid-cooling radiator as claimed in claim 3, wherein at least one fin that is flexible is disposed in the flow channel.

10. The liquid-cooling radiator as claimed in claim 7, wherein the at least one fin has a through hole; the through hole penetrates through the cooling surface and the abutting surface.

11. The liquid-cooling radiator as claimed in claim 8, wherein the at least one fin has a through hole; the through hole penetrates through the cooling surface and the abutting surface.

12. The liquid-cooling radiator as claimed in claim 9, wherein the at least one fin has a through hole; the through hole penetrates through the cooling surface and the abutting surface.

13. A heat pipe of a liquid-cooling radiator, comprising a pipe body that is flexible, wherein the pipe body has a flow channel; the flow channel has a flow channel inlet and a flow channel outlet; two opposite sides of the pipe body respectively have a cooling surface and an abutting surface; at least one fin that is flexible is disposed in the flow channel.

14. The heat pipe as claimed in claim 13, wherein the at least one fin has a through hole; the through hole penetrates through the cooling surface and the abutting surface.

15. The heat pipe as claimed in claim 13, wherein the at least one fin includes a plurality of fins; the plurality of fins are grouped in pairs and are arranged at intervals along an extending direction of the flow channel; a flow direction of a fluid in the flow channel toward the flow channel outlet is defined as a downstream direction and a flow direction of the fluid in the flow channel toward the flow channel inlet is defined as an upstream direction; a distance between two ends of each of the pairs of the plurality of fins facing the upstream direction is larger than a distance between two another ends of each of the pairs of the plurality of fins facing the downstream direction.

16. The heat pipe as claimed in claim 13, wherein the at least one fin includes a plurality of fins; the plurality of fins are sheet-like and are configured in a direction the same as an extending direction of the flow channel; the plurality of fins are arranged in a staggered arrangement in a direction perpendicular to the extending direction of the flow channel and are arranged along the extending direction of the flow channel.

17. The heat pipe as claimed in claim 13, wherein the at least one fin includes a plurality of fins; the plurality of fins are sheet-like and are configured in a direction perpendicular to an extending direction of the flow channel; the plurality of fins are arranged in a staggered arrangement in the direction perpendicular to the extending direction of the flow channel and are arranged along the extending direction of the flow channel.

18. The heat pipe as claimed in claim 13, wherein the flow channel inlet and the flow channel outlet of the flow channel face a same direction; a notch is formed at a part of the pipe body located between the flow channel inlet and the flow channel outlet; a part of the pipe body adjacent to an inner side of the notch has a stopping surface.

19. The heat pipe as claimed in claim 14, wherein the flow channel inlet and the flow channel outlet of the flow channel face a same direction; a notch is formed at a part of the pipe body located between the flow channel inlet and the flow channel outlet; a part of the pipe body adjacent to an inner side of the notch has a stopping surface.

20. The heat pipe as claimed in claim 15, wherein the flow channel inlet and the flow channel outlet of the flow channel face a same direction; a notch is formed at a part of the pipe body located between the flow channel inlet and the flow channel outlet; a part of the pipe body adjacent to an inner side of the notch has a stopping surface.
